(19) United States
(12) Patent Application Publication
(10) Pub. No.: US 2012/0138125 A1
(43) Pub. Date: Jun. 7, 2012

(54) FLUORESCENT SOLAR CONVERSION CELLS BASED ON FLUORESCENT TERYLENE DYES

(75) Inventors: Markus HAMMERMANN, Dossenheim (DE); Martin Könemann, Mannheim (DE); Alfred Rennig, Boechingen (DE); Axel Grimm, Heidelberg (DE); Arno Böhm, Mannheim (DE); Peter Erk, Frankenthal (DE)

(73) Assignee: BASF SE, Ludwigshafen (DE)

(21) Appl. No.: 13/187,976

(22) Filed: Jul. 21, 2011

Related U.S. Application Data
(63) Continuation of application No. 12/065,620, filed on Mar. 4, 2008, now abandoned.

(30) Foreign Application Priority Data
Sep. 12, 2005 (DE) 10 2005 043 572.6

(51) Int. Cl. H01L 31/055

(52) U.S. Cl. 136/247

(57) ABSTRACT

A fluorescence conversion solar cell based on one or more panels composed of polymer doped with at least one fluorescent dye and/or glass panels coated with the doped polymer and photovoltaic cells mounted on the edges of the panels, which comprise one or more fluorescent dyes based on terrylenecarboxylic acid derivatives or a combination of these fluorescent dyes with further fluorescent dyes.

The present invention relates to fluorescence conversion solar cells based on one or more panels composed of polymer doped with at least one fluorescent dye and/or glass panels coated with the doped polymer and photovoltaic cells mounted on the edges of the panels, which comprise one or more fluorescent dyes based on terrylenecarboxylic acid derivatives or a combination of these fluorescent dyes with further fluorescent dyes.

Fundamentally, photovoltaic cells can convert the incident sunlight only partly to electrical energy; a large part of the energy is lost in the form of heat. For example, a silicon solar cell can absorb all photons which have an energy above the band edge of 1.1 eV of crystalline silicon, i.e. a wavelength of 1300 nm. The excess energy of the absorbed photons is converted to heat and leads to heating of the photovoltaic cell. This reduces its efficiency.

Therefore, as early as the 1970s, fluorescence conversion cells were described which are a combination of photovoltaic cells with fluorescent light collecting systems (solar collectors) and enable better utilization of the energy of sunlight. The solar collectors convert the absorbed sunlight to light which is of a longer wavelength but is still above the silicon band edge in energetic terms and thus reduce the heating of the photovoltaic cell. Use of a plurality of fluorescers which absorb and emit at different wavelengths (known as cascades) allows the incident sunlight to be converted particularly effectively to light of energy suitable for the photovoltaic cell.

Moreover, the surface area which is to be equipped with photovoltaic cells is reduced by the use of fluorescent solar collectors. Thus, the light is guided into the panels comprising the fluorescer or coated with it by total reflection to the nonreflective edge and concentrated there, and only this edge has to be covered with photovoltaic cells. This allows the costs of the overall setup to be reduced distinctly.

The construction and the way in which these fluorescence conversion solar cells work is known from Appl. Phys. 14, 123-139 (1977) and U.S. Pat. No. 4,110,123.

Nature 274, 144-145 (1978) and U.S. Pat. No. 4,367,367 describe fluorescence conversion solar cells based on a plurality of glass plates doped with fluorescent metal ions such as UO₂²⁺, Eu³⁺, Cr³⁺, Yb³⁺ and Nd³⁺, and coated with fluorescent dyes (violanthrone, Rhodamine 6G) in PMMA matrix.

EP-A-073 007 also discloses the use of alkoxylated violanthrones and isoviolanthrones as fluorescent dyes for solar collectors.

EP-A-041 274 describes the use of vat dyes, including perylenetetracarboximides, in fluorescence conversion solar cells.

Owing to their photostability, fluorescent dyes based on perylene are of particular interest for use in fluorescence conversion solar cells.

In Nachr. Chem. Tech. Lab. 28, 716-718 (1980), N,N′-bis(2,5-di-tert-butyl-phenyl)perylenetetracarboximide is used for this purpose. DE-A-32 35 526 and 35 45 004 disclose the use of perylenetetracarboximides substituted, including tetraphenoxy-substituted and tetrahalogenated, in the perylene skeleton for areal concentration of light. WO-A-97/08756 describes solar collectors based on polycarbonate panels which comprise fluorescent dyes based on perylene (N,N′-bis(2,6-diisopropylphenyl)perylene-tetracarboximide and diisobutyl perylene-3,9- or -3,10-dicarboxylate) in combination with sterically hindered amines as stabilizers. Finally, ECN report ECN-RX-05-009: 20th European Photovoltaic Solar Energy Conference and Exhibition (Barcelona, Spain; 6-10 Jun. 2005) presents a fluorescence conversion solar cell comprising N,N′-bis(7-tridecyl)perylenetetracarboximide and a red coumarin dye.

The systems described to date have not yet been utilized commercially. One reason for this is that the fluorescent dyes proposed do not have sufficient light stability and/or only make accessible too small a wavelength range of sunlight by fluorescence conversion for the photovoltaic cell.

It was an object of the invention to remedy these deficiencies and to provide fluorescence conversion solar cells which can be used advantageously to convert sunlight to electrical energy.

Accordingly, fluorescence conversion solar cells based on one or more panels composed of polymer doped with at least one fluorescent dye and/or glass panels coated with the doped polymer and photovoltaic cells mounted on the edges of the panels have been found, which comprise one or more fluorescent dyes based on terrylenecarboxylic acid derivatives or a combination of these fluorescent dyes with further fluorescent dyes.

The inventive fluorescence conversion solar cells preferably comprise at least one fluorescent dye which is based on terrylenecarboxylic acid derivatives and emits in the NIR in combination with at least one fluorescent dye absorbing and emitting at shorter wavelength. More preferably, the emission maximum of the dye absorbing at a shorter wavelength in each case and the absorption maximum of the next dye agree substantially (dye cascade).

When the fluorescent dye based on terrylene is a polychromophore, i.e. a dye which combines the units of various chromophores in one molecule, the light emitted in the dye molecule is shifted bathochromically; a physical mixture of different dyes can be at least partly avoided.

The inventive fluorescence conversion solar cell can be constructed from one polymer panel doped with the fluorescent dye(s) or a glass panel coated with the doped polymer or a plurality of such panels or else combinations of the polymer and glass panels.

When a combination of different fluorescent dyes is used, the fluorescent dye based on terrylene is preferably used in a separative polymer panel or polymer coating.

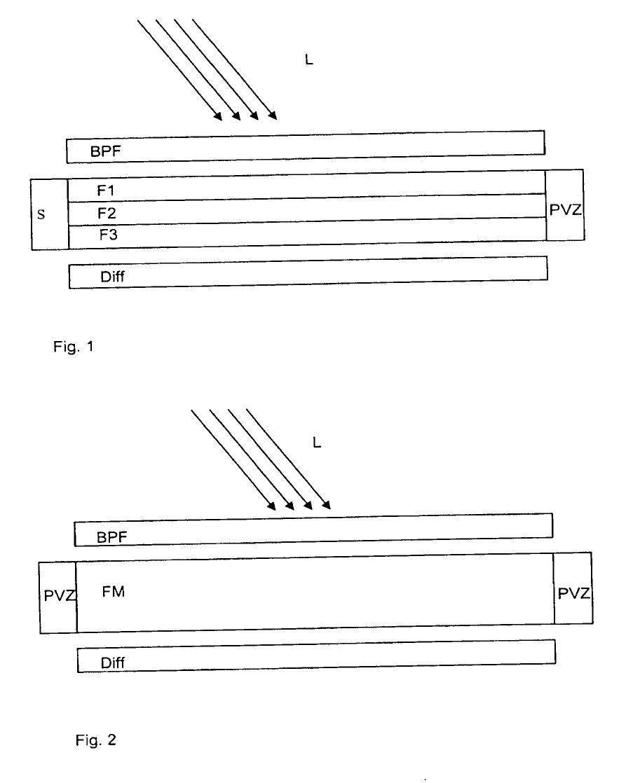

FIG. 1 shows the schematic structure of a fluorescence conversion solar cell of the panel stack type.

FIG. 2 shows a fluorescence conversion solar cell based on a polymer panel.

The fluorescence conversion solar cell shown by way of example in FIG. 1 is constructed from three polymer panels doped with different fluorescent dyes (F1 to F3). The uppermost panel (F1) has preferably been doped in high concentration with the fluorescent dye absorbing at the shortest wavelength, the middle panel (F2) comprises a fluorescent dye absorbing at medium wavelength and the uppermost panel (F3) has finally been doped with the fluorescent dye emitting in the NIR.

One or more edges of the polymer panel stack are covered with in each case one or more photovoltaic cells (PVZ); the uncovered edges are reflective (S).

The photovoltaic cell PVZ may be constructed from customary materials, for example from crystalline, polycrystalline, amorphous or thin-film silicon, CIS (CuInSe₂), CdTe, GaAs, InP or GaInAsP.

The polymer panels may be joined to one another with optical coupling or via gas-filled (e.g. air-filled) interstices.

In order to conduct the light emitted outside the total reflection angle (approx. 20%) into the panel, it is optionally possible to apply a selectively reflecting bandpass filter layer (BPF) to the illumination side (L).

If desired, a UV-absorbing layer and/or a scratch-resistant coating may be applied to the upper side of the uppermost polymer panel (F1) for protection.

The transmitted light is scattered back into the fluorescence conversion solar cell by means of a diffuse (white) reflector (diff) or a mirror.

The fluorescence conversion solar cell shown in FIG. 2 is based on a polymer panel which has been doped with a mixture of fluorescence dyes (FM).

The cell shown by way of example has a photovoltaic cell (PVZ) at both edges.

The further structure corresponds to that of the fluorescence conversion solar cell of the panel stack type.

The inventive fluorescence conversion solar cells comprise preferably at least one fluorescent dye from the group of the terrylenetetracarboximides, terrylenetetracarboxylic monoanhydride monoimides, terrylenetetracarboxylic dianhydrides, terrylenedicarboximides, terrylenedicarboxylic anhydrides, condensation products of terrylenetetra- and -dicarboxylic anhydrides with aromatic diamines and polychromophores having terrylene units.

In each case, the term “carboxylic anhydride” shall also encompass the acid present in free form or as a salt.

The fluorescent dyes based on a terrylene unit as the sole chromophore (referred to as “terrylene dyes Ia” for short) preferably have the general formula Ia

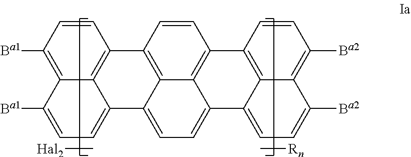

in which the variables are each defined as follows:
B^{a1} are joined together with formation of a six-membered ring to give a radical of the formula (a), (b) or (c)

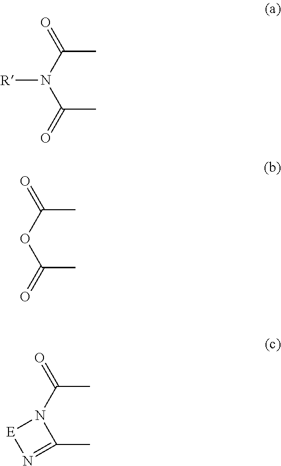

both are hydrogen or a —COOM radical or one of the two radicals is an R radical or bromine and the other radical is hydrogen;
B^{a2}, independently of B^{a1}, are joined together with formation of a six-membered ring to give a radical of the formula (a), (b) or (c), or are both a —COOM radical;
R is aryloxy, arylthio, hetaryloxy or hetarylthio, to each of which may be fused further saturated or unsaturated 5- to 7-membered rings whose carbon skeleton may be interrupted by one or more —O—, —S—, —NR¹—, —N—CR¹—, —CO—, —SO— and/or —SO₂— moieties, where the entire ring system may be mono- or polysubstituted by the (i), (ii), (iii), (iv) and/or (v) radicals:
   (i) C₁-C₃₀-alkyl whose carbon chain may be interrupted by one or more —O—, —S—, —NR¹—, —N═CR¹—, —C≡C—, —CR¹═CR¹—, —CO—, —SO— and/or —SO₂— moieties and which may be mono- or polysubstituted by: C₁-C₁₂-alkoxy, C₁-C₆-alkylthio, —C≡CR¹, —CR¹═CR¹₂, hydroxyl, mercapto, halogen, cyano, nitro, —NR²R³, —NR²COR³, —CONR²R³, —SO₂NR²R³, —COOR², —SO₃R², aryl and/or saturated or unsaturated C₄-C₇-cycloalkyl whose carbon skeleton may be interrupted by one or more —O—, —S—, —NR¹—, —N═CR¹—, —CR¹═CR¹—, —CO—, —SO— and/or —SO₂— moieties, where the aryl and cycloalkyl radicals may each be mono- or polysubstituted by C₁-C₁₈-alkyl and/or the above radicals specified as substituents for alkyl;
   (ii) C₃-C₈-cycloalkyl whose carbon skeleton may be interrupted by one or more —O—, —S—, —NR¹—, —N═CR¹—, —CR¹═CR¹—, —CO—, —SO— and/or —SO₂— moieties and to which may be fused further saturated or unsaturated 5- to 7-membered rings whose carbon skeleton may be interrupted by one or more —O—, —S—, —NR¹—, —N═CR¹—, —CR¹═CR¹—, —CO—, —SO— and/or —SO₂— moieties, where the entire ring system may be mono- or polysubstituted by: C₁-C₁₈-alkyl, C₁-C₁₂-alkoxy, C₁-C₆-alkylthio, —C≡CR¹, —CR¹═CR¹₂, hydroxyl, mercapto, halogen, cyano, nitro, —NR²R³, —NR²COR³, —CONR²R³, —SO₂NR²R³, —COOR² and/or —SO₃R²;
   (iii) aryl or hetaryl, to each of which may be fused further saturated or unsaturated 5- to 7-membered rings whose carbon skeleton may be interrupted by one or more —O—, —S—, —NR¹—, —N═CR¹—, —CR¹═CR¹—, —CO—, —SO— and/or —SO₂— moieties, where the entire ring system may be mono- or polysubstituted by: C₁-C₁₈-alkyl, C₁-C₁₂-alkoxy, C₁-C₆alkylthio, —C≡CR¹, —CR¹═CR¹₂, hydroxyl, mercapto, halogen, cyano, nitro, —NR²R³, —NR²COR³, —CONR²R³, —SO₂NR²R³, —COOR², —SO₃R², aryl and/or hetaryl, each of which may be mono- or polysubstituted by C₁-C₁₈-alkyl, C₁-C₁₂-alkoxy, hydroxyl, mercapto, halogen, cyano, nitro, —NR²R³, —NR²COR³, —CONR²R³, —SO₂NR²R³, —COOR² and/or —SO₃R²;
   (iv) a -U-aryl radical which may be mono- or polysubstituted by the above radicals specified as substituents for the aryl radicals (iii), where U is an —O—, —S—, —NR¹—, —CO—, —SO— or —SO₂— moiety;
(v) C₁-C₁₂-alkoxy, C₁-C₆-alkylthio, —C≡CR¹, —CR¹═CR¹₂, hydroxyl, mercapto, halogen, cyano, nitro, —NR²R³, —NR²COR³, —CONR²R³, —SO₂NR²R³, —COOR² or —SO₃R²,
   where the R radicals may be the same or different when n >1;
R¹ is hydrogen or C₁-C₁₈-alkyl, where the R¹ radicals may be the same or different when they occur more than once;
R²,R³ are each independently hydrogen;
   C₁-C₁₈-alkyl whose carbon chain may be interrupted by one or more —O—, —S—, —CO—, —SO— and/or —SO₂— moieties and which may be mono- or polysubstituted by C₁-C₁₂-alkoxy, C₁-C₆-alkylthio, hydroxyl, mercapto, halogen, cyano, nitro and/or —COOR¹;
   aryl or hetaryl, to each of which may be fused further saturated or unsaturated 5- to 7-membered rings whose carbon skeleton may be interrupted by one or more —O—, —S—, —CO— and/or —SO₂— moieties, where the entire ring system may be mono- or polysubstituted by C₁-C₁₂-alkyl and/or the above radicals specified as substituents for alkyl;
Hal is bromine or cyano;
R′ is C₄-C₃₀-alkyl whose carbon chain may be interrupted by one or more —O—, —S—, —NR¹—, —N═CR¹—, —C≡C—, —CR¹═CR¹—, —CO—, —SO— and/or —SO₂— moieties and which may be mono- or polysubstituted by the (ii), (iii), (iv) and/or (v) radicals specified as substituents for the R radicals;
   C₃-C₈-cycloalkyl to which may be fused further saturated or unsaturated 5- to 7-membered rings whose carbon skeleton may be interrupted by one or more —O—, —S—, —NR¹—, —N═CR¹′, —CR¹═CR¹—, —CO—, —SO— and/or —SO₂— moieties, where the entire ring system may be mono- or polysubstituted by the (i), (ii), (iii), (iv) and/or (v) radicals specified as substituents for the R radicals;
   aryl or hetaryl, to each of which may be fused further saturated or unsaturated 5- to 7-membered rings whose carbon skeleton may be interrupted by one or more —O—, —S—, —NR¹—, —N═CR¹, —CR¹═CR¹—, —CO—, —SO— and/or —SO₂— moieties, where the entire ring system may be mono- or polysubstituted by the (i), (ii), (iii), (iv), (v) radicals specified as substituents for the R radicals, and/or aryl- and/or hetarylazo, each of which may be mono- or polysubstituted by C₁-C,₁₀-alkyl, C₁-C₆-alkoxy and/or cyano;
E is 1,2-phenylene, 1,8- or 2,3-naphthylene or 2,3- or 3,4-pyridylene, each of which may be substituted by C₁-C,₂-alkyl, C₁-C₆-alkoxy, hydroxyl, nitro and/or halogen;
M is hydrogen, alkali metal cation, [NH₄]⁺ or [NR²₄]⁺;
n is from 2 to 6 or else 0 when (1) the B^{a1} and B^{a2} radicals are each a radical of the formula (a) or (2) the B^{a1} radicals are a radical of the formula (a) and the B^{a2} radicals are both hydrogen or one of the two B^{a2} radicals is bromine and the other B^{a2} radical is hydrogen;
z is from 0 to 6, where n+z≦6 and z may only be different from 0 when the B^{a1} and B^{a2} radicals are each a radical of the formula (a).

The terrylene dyes Ia and their preparation are described in WO-A-03/104 232 and 02/66438, WO-A-2006/058674, which was unpublished at the priority date of the present application, and also the prior German patent applications 10 2005 021 362.6, 10 2005 032 583.1 and 10 2005 037 115.9.

In the case of the terrylenetetracarboximides and terrylenedicarboximides, the terrylene dyes la may be unsubstituted in the terrylene skeleton (bay positions). Otherwise, they are substituted by from 1 to 6 substituents, preferably in the 1,6,9,14-position by 4 R substituents, or else by Hal in the case of the terrylenetetracarboximides.

The brominated terrylene dyes la also serve as the starting material for the terrylene dyes Ia substituted by the R radicals. Bromine atoms may therefore also be present in the terrylene dyes la owing to an incomplete exchange.

Particularly preferred terrylene dyes la are substituted in the terrylene skeleton by the aryloxy, arylthio, hetaryloxy or hetaylthio radicals R, especially phenoxy, thiophenoxy, pyridyloxy, pyrimidyloxy, pyridylthio or pyrimidylthio radicals R.

Very particular preference is given to terrylene dyes Ia which are substituted by 4 R radicals.

Preferred R radicals are phenoxy or thiophenoxy radicals, each of which may be mono- or polysubstituted by identical or different (i), (ii), (iii), (iv) and/or (v) radicals:

(i) C₁-C₃₀-alkyl whose carbon chain may be interrupted by one or more —O—, —S—, —NR¹—, —C≡C—, —CR¹═CR¹— and/or —CO— moieties and which may be mono- or polysubstituted by: C₁-C₁₂-alkoxy, hydroxyl, halogen, cyano, and/or aryl which may be mono- or poly-substituted by C₁-C₁₈-alkyl or C₁-C₆-alkoxy;

(ii) C₃-C₈-cycloalkyl whose carbon skeleton may be interrupted by one or more —O—, —S—, —NR¹—, —CR¹═CR¹— and/or —CO— moieties and which may be mono- or polysubstituted by: C₁-C₁₈-alkyl, C₁-C₁₂-alkoxy and/or C₁-C₆-alkylthio;

(iii) aryl or hetaryl, to each of which may be fused further saturated or unsaturated 5- to 7-membered rings whose carbon skeleton may be interrupted by one or more —O—, —S—, —NR¹—, —N═CR¹—, —CR¹═CR¹—, —CO—, —SO— and/or —SO₂— moieties, where the entire ring system may be mono- or polysubstituted by: C₁-C₁₈-alkyl, C₁-C₁₂-alkoxy, —C═CR¹—, —CR¹═CR¹, hydroxyl, halogen, cyano, —NR²R³, —NR²COR³, —CONR²R³, —SO₂NR²R³, —COOR² and/or —SO₃R²;

(iv) a -U-aryl radical which may be mono- or polysubstituted by the above radicals specified as substituents for the aryl radicals (iii), where U is an —O—, —S—, —NR¹—, —CO—, —SO— or —SO₂— moiety;

(v) C₁-C₁₂-alkoxy, C₁-C₆-alkylthio, —C≡CR¹, —CR¹═CR¹₂, hydroxyl, mercapto, halogen, cyano, nitro, —NR²R³, —NR²COR³, —CONR²R³, —SO₂NR²R³, —COOR² or —SO₃R².

The (thio)phenoxy radicals R may be unsubstituted or monosubstituted in the ortho-, meta- or preferably para-position. They may also be di-, tri-, tetra- or pentasubstituted, in which case all conceivable substitution patterns are possible.

Particularly preferred R radicals are ortho, ortho′-disubstituted (thio)phenoxy radicals of the formula

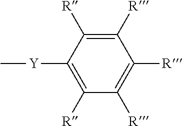

The R″ radicals in the two ortho positions may be the same or different, but they are preferably the same.

The (thio)phenoxy radicals R may also be substituted in one, two or all three further ring positions by identical or nonidentical R′″ radicals other than hydrogen.

The (thio)phenoxy radicals R are preferably substituted only in the ortho- and ortho′-position or additionally in the para-position.

In particular, the variables in the above formula are each defined as follows:
Y is —O—or —S—, preferably —O—;
R′ are identical or different radicals:
   (i) C₁-C₁₈-alkyl whose carbon chain may be interrupted by one or more —O—, —S—, —NR¹— and/or —CO— moieties and which may be mono- or polysubstituted by C₁-C₁₂-alkoxy, hydroxyl and/or halogen, where no more than one of the alkyl radicals R″ may have a tertiary carbon atom in the 1-position;
(ii) C₃-C₈-cycloalkyl, which may be mono- or polysubstituted by C₁-G₁₈-alkyl and/or C₁-C₁₂-alkoxy, where no more than one of the R″ radicals may have a tertiary carbon atom in the 1-position;
   (iii) aryl or hetaryl, each of which may be mono- or polysubstituted by C₁-C₁₈-alkyl, C₁-C₁₂-alkoxy, hydroxyl and/or halogen;
   (iv) a -U-aryl radical which may be mono- or polysubstituted by the above radicals specified as substituents for the aryl radicals (iii), where U is an —O—, —S— or —NR¹— moiety;
   (v) C₁-C₁₂-alkoxy, hydroxyl, halogen or cyano;
R″ are identical or different radicals:
   hydrogen;
   one of the (i), (ii), (iii), (iv) and (v) radicals specified for R, where the alkyl radicals (i) and the cycloalkyl radicals (ii) may have a tertiary carbon atom in the 1-position;
R¹ is hydrogen or C₁-C₆-alkyl.

Preferred R″ radicals are alkyl, cycloalkyl and phenyl radicals, in particular alkyl radicals with a secondary or primary carbon atom in the 1-position, and also methyl and cycloalkyl radicals with a secondary carbon atom in the 1-position, particular emphasis being given to the alkyl and cycloalkyl radicals with a secondary carbon atom in the 1-position.

Specific examples of particularly preferred (thio)phenoxy radicals include:

2,6-dimethylphenoxy, 2,6-diethylphenoxy, 2,6-diisopropylphenoxy, 2,6-di(2-butyl)-phenoxy, 2,6-di(n-butyl)phenoxy, 2,6-di(2-hexyl)phenoxy, 2,6-di(n-hexyl)phenoxy, 2,6-di(2-dodecyl)phenoxy, 2,6-di(n-dodecyl)phenoxy, 2,6-dicyclohexylphenoxy, 2,6-diphenylphenoxy, 2,6-di-methyl-4-(n-butyl)phenoxy, 2,6-diethyl-4-(n-butyl)phenoxy, 2,6-diisopropyl-4-(n-butyl)phenoxy, 2,6-di(2-butyl)-4-(n-butyl)phenoxy, 2,4,6-tri(n-butyl)phenoxy, 2,6-di(2-hexyl)-4-(n-butyl)phenoxy, 2,6-di(n-hexyl)-4-(n-butyl)phenoxy, 2,6-di(2-dodecyl)-4-(n-butyl)phenoxy, 2,6-di(n-dodecyl)-4-(n-butyl)phenoxy, 2,6-dicyclohexyl-4-(n-butyl)phenoxy, 2,6-diphenyl-4-(n-butyl)phenoxy, 2,6-dimethyl-4-(n-nonyl)phenoxy, 2,6-diethyl-4-(n-nonyl)phenoxy, 2,6-diiso-propyl-4-(n-nonyl)phenoxy, 2,6-di(2-butyl)-4-(n-nonyl)phenoxy, 2,6-di(2-butyl)-4-(n-nonyl)phenoxy, 2,6-di(2-hexyl)-4-(n-nonyl)phenoxy, 2,6-di(n-hexyl)-4-(n-nonyl)phenoxy, 2,6-di(2-dodecyl)-4-(n-nonyl)phenoxy, 2,6-di(n-dodecyl)-4-(n-nonyl)phenoxy, 2,6-dicyclohexyl-4-(n-nonyl)phenoxy, 2,6-diphenyl-4-(n-nonyl)phenoxy, 2,6-dimethyl-4-(n-octadecyl)phenoxy, 2,6-diethyl-4-(n-octadecyl)phenoxy, 2,6-diisopropyl-4-(n-octadecyl)phenoxy, 2,6-di(2-butyl)-4-(n-octadecyl)phenoxy, 2,6-di(2-butyl)-4-(n-octadecyl)phenoxy, 2,6-di(2-hexyl)-4-(n-octadecyl)phenoxy, 2,6-di(n-hexyl)-4-(n-octadecyl)phenoxy, 2,6-di(2-dodecyl)-4-(n-octadecyl)phenoxy, 2,6-di(n-dodecyl)-4-(n-octadecyl)phenoxy, 2,6-dicyclohexyl-4-(n-octadecyl)phenoxy, 2,6-dimethyl-4-(tert-butyl)phenoxy, 2,6-diethyl-4-(tert-butyl)phenoxy, 2,6-diisopropyl-4-(tert-butyl)phenoxy, 2,6-di(2-butyl)-4-(tert-butyl)phenoxy, 2,6-di-(n-butyl)-4-(tert-butyl)phenoxy, 2,6-di(2-hexyl)-4-(tert-butyl)-phenoxy, 2,6-di(n-hexyl)-4-(tert-butyl)phenoxy, 2,6-di(2-dodecyl)-4-(tert-butyl)-phenoxy, 2,6-di(n-dodecyl)-4-(tert-butyl)phenoxy, 2,6-dicyclohexyl-4-(tert-butyl)-phenoxy, 2,6-diphenyl-4-(tert-butyl)phenoxy, 2,6-dimethyl-4-(tert-octyl)phenoxy, 2,6-diethyl-4-(tert-octyl)phenoxy, 2,6-diisopropyl-4-(tert-octyl)phenoxy, 2,6-di(2-butyl)-4-(tert-octyl)phenoxy, 2,6-di(n-butyl)-4-(tert-octyl)phenoxy, 2,6-di(2-hexyl)-4-(tert-octyl)phenoxy, 2,6-di(n-hexyl)-4-(tert-octyl)phenoxy, 2,6-di(2-dodecyl)-4-(tert-octyl)phenoxy, 2,6-di(n-dodecyl)-4-(tert-octyl)phenoxy, 2,6-dicyclohexyl-4-(tert-octyl)phenoxy and 2,6-diphenyl-4-(tert-octyl)phenoxy;

2,6-dimethyithiophenoxy, 2,6-diethylthiophenoxy, 2,6-diisopropylthiophenoxy, 2,6-di(2-butyl)thiophenoxy, 2,6-di(n-butyl)thiophenoxy, 2,6-di(2-hexyl)thiophenoxy, 2,6-di(n-hexyl)thiophenoxy, 2,6-di(2-dodecyl)thiophenoxy, 2,6-di(n-dodecyl)thiophenoxy, 2,6-dicyclohexylthiophenoxy, 2,6-diphenylthiophenoxy, 2,6-dimethyl-4-(n-butyl)thiophenoxy, 2,6-diethyl-4-(n-butyl)thiophenoxy, 2,6-diisopropyl-4-(n-butyl)thiophenoxy, 2,6-di(2-butyl)-4-(n-butyl)-thiophenoxy, 2,4,6-tri(n-butyl)thiophenoxy, 2,6-di(2-hexyl)-4-(n-butyl)thiophenoxy, 2,6-di(n-hexyl)-4-(n-butyl)thiophenoxy, 2,6-di(2-dodecyl)-4-(n-butyl)thiophenoxy, 2,6-di(n-dodecyl)-4-(n-butyl)thiophenoxy, 2,6-dicyclohexyl-4-(n-butyl)thiophenoxy, 2,6-diphenyl-4-(n-butyl)-thiophenoxy, 2,6-di-methyl-4-(n-nonyl)thiophenoxy, 2,6-diethyl-4-(n-nonyl)thiophenoxy, 2,6-diisopropyl-4-(n-nonyl)thiophenoxy, 2,6-di(2-butyl)-4-(n-nonyl)thiophenoxy, 2,6-di(2-butyl)-4-(n-nonyl)thiophenoxy, 2,6-di(2-hexyl)-4-(n-nonyl)thiophenoxy, 2,6-di(n-hexyl)-4-(n-nonyl)-thiophenoxy, 2,6-di(2-dodecyl)-4-(n-nonyl)thiophenoxy, 2,6-di(n-dodecyl)-4-(n-nonyl)-thiophenoxy, 2,6-dicyclohexyl-4-(n-nonyl)thiophenoxy, 2,6-diphenyl-4-(n-nonyl)thiophenoxy, 2,6-(dimethyl)-4-(n-octadecyl)-thiophenoxy, 2,6-(diethyl)-4-(n-octadecyl)thiophenoxy, 2,6-diisopropyl-4-(n-octadecyl)-thiophenoxy, 2,6-di(2-butyl)-4-(n-octadecyl)thiophenoxy, 2,6-di(2-butyl)-4-(n-octade-cyl)thiophenoxy, 2,6-di(2-hexyl)-4-(n-octadecyl)thiophenoxy, 2,6-di(n-hexyl)-4-(n-octa-decyl)thiophenoxy, 2,6-di(2-dodecyl)-4-(n-octadecyl)thiophenoxy, 2,6-di(n-dodecyl)-4-(n-octadecyl)thiophenoxy, 2,6-dicyclohexyl-4-(n-octadecyl)-thiophenoxy, 2,6-dimethyl-4-(tert-butyl)thiophenoxy, 2,6-diethyl-4-(tert-butyl)thiophenoxy, 2,6-diisopropyl-4-(tert-butyl)thiophenoxy, 2,6-di(2-butyl)-4-(tert-butyl)thiophenoxy, 2,6-di-(n-butyl)-4-(tent-butyl)thiophenoxy, 2,6-di(2-hexyl)-4-(tert-butyl)thiophenoxy, 2,6-di(n-hexyl)-4-(tert-butyl)thiophenoxy, 2,6-di(2-dodecyl)-4-(tert-butyl)thiophenoxy, 2,6-di(n-dodecyl)-4-(tert-butyl)thiophenoxy, 2,6-dicyclohexyl-4-(tert-butyl)thiophenoxy, 2,6-diphenyl-4-(tert-butyl)thiophenoxy, 2,6-dimethyl-4-(tert-octyl)thiophenoxy, 2,6-diethyl-4-(tert-octyl)thiophenoxy, 2,6-diisopropyl-4-(tert-octyl)thiophenoxy, 2,6-di(2-butyl)-4-(tert-octyl)thiophenoxy, 2,6-di-(n-butyl)-4-(tert-octyl)thiophenoxy, 2,6-di(2-hexyl)-4-(tert-octyl)thiophenoxy, 2,6-di(n-hexyl)-4-(tert-octyl)thiophenoxy, 2,6-di(2-dodecyl)-4-(tert-octyl)thiophenoxy, 2,6-di(n-dodecyl)-4-(tert-octyl)thiophenoxy, 2,6-dicyclohexyl-4-(tert-octyl)thiophenoxy and 2,6-diphenyl-4-(tert-octyl)thiophenoxy.

The terrylene dyes la preferably comprise at least one imide function, i.e. preference is given to the terrylenetetracarboximides, terrylenetetracarboxylic monoanhydride monoimides, terrylenedicarboximides and the monocondensation products of terrylenetetracarboxylic dianhydrides with aromatic diamines, said products still having an imide function.

The terrylene dyes la more preferably comprise exclusively imide functions. Particular preference is thus given to the terrylenetetracarboximides and terrylenedicarboximides, very particular preference being given to the terrylenetetracarboximides.

The substituent R′ on the imide nitrogen atom is in particular defined as follows:

C₄-C₃₀-alkyl whose carbon chain may be interrupted by one or more —O—and/or —CO— moieties and which may be mono- or polysubstituted by: C₁-C₆-alkoxy, cyano and/or aryl each of which may be substituted by C₁-C₁₆-alkyl and/or C₁-C₆-alkoxy;

C₅-C₈-cycloalkyl which may be mono- or polysubstituted by C₁-C₁₂-alkyl;

phenyl, naphthyl, pyridyl or pyrimidyl, each of which may be mono- or polysubstituted by: C₁-C₁₈-alkyl, C₁-C₆-alkoxy, halogen, cyano, nitro, —CONR²R³, —SO₂NR²R³ and/or phenyl- and/or naphthylazo, each of which may be mono- or polysubstituted by C₁-C₁₀-alkyl, C₁-C₆-alkoxy and/or cyano.

R′ is more preferably defined as follows:

C₄-C₃₀-alkyl whose carbon chain may be interrupted by one or more —O—and/or —CO— moieties and which may be mono- or polysubstituted by: C₁-C₆-alkoxy, cyano and/or aryl each of which may be substituted by C₁-C₁₈-alkyl and/or C₁-C₆-alkoxy;

C₅-C₈-cycloalkyl which may be mono- or polysubstituted by C₁-C₆-alkyl;

phenyl, naphthyl, pyridyl or pyrimidyl, each of which may be mono- or polysubstituted by: C₁-C₁₈-alkyl, C₁-C₆-alkoxy, halogen, cyano, nitro, —CONR²R³, —SO²NR²R³ and/or phenyl- and/or naphthylazo, each of which may be mono- or polysubstituted by C₁-C₁₀-alkyl, C₁-C₆-alkoxy and/or cyano.

R² and R³ are each independently:

hydrogen;

C₁-C₁₈-alkyl which may be mono- or polysubstituted by C₁-C₆-alkoxy, hydroxyl, halogen and/or cyano;

aryl or hetaryl, each of which may be mono- or polysubstituted by C₁-C₆-alkyl and/or the aforementioned radicals specified as substituents for alkyl.

The R′ radicals preferably have from 4 to 24 carbon atoms in order to ensure sufficient solubility and fluorescence.

Very particularly preferred R′ radicals are ortho,ortho′-dialkyl-substituted aryl radicals, in particular those which are also part of the R radical, and linear alkyl chains which are bonded to the imide nitrogen atom via an internal carbon atom. Selected examples of these R radicals are 2,6-dimethylphenyl, 2,6-diisopropylphenyl, 2,6-diisopropyl-4-butylphenyl, 5-undecyl, 7-tridecyl and 9-pentadecyl.

Examples of preferred terrylene dyes Ia include:

N,N′-Bis(2,6-diisopropylphenyl)terrylene-3,4:11,12-tetracarboximide, N,N′-bis(7-tridecyl)terrylene-3,4:11,12-tetracarboximide, N,N′-bis(2,6-diisopropylphenyl)-1,6,9,14-tetra(4-tert-octylphenoxy)terrylene-3,4:11,12-tetracarboximide, N,N′-bis(2,6-diisopropyl-phenyl)-1,6,9,14-tetra(2,6-diisopropylphenoxy)terrylene-3,4:11,12-tetracarboximide, N-(2,6-diisopropylphenyl)terrylene-3,4-dicarboximide, N-(7-tridecyl)terrylene-3,4-dicarboximide, N-(2,6-diisopropylphenyl)-1,6,9,14-tetra(4-tert-octylphenoxy)terrylene-3,4-dicarboximide and N-(2,6-diisopropylphenyl)-1,6,9,14-tetra(2,6-diisopropyl-phenoxy)terrylene-3,4-dicarboximide.

The inventive fluorescence conversion solar cells may also comprise polychromophores with terrylene units as a fluorescent dye.

In this case, the terrylene chromophore preferably forms the central unit to which the further chromophores, preferably perylene and/or naphthalene chromophores, are bonded. However, the chromophores may also be arranged in reverse sequence.

The type of linkage is determined by the form of the polychromophore molecule. For example, the linkage of a central N,N′-bis(2,6-diisopropylphenoxy)terrylenetetra-carboximide molecule with 4 or 8 N-(2,6-diisopropylphenyl)perylenedicarboximide units or with 4 N-(2,6-diisopropylphenyl)perylenedicarboximide units and 8 N-(2,6-diisopropylphenyl)naphthalenedicarboximide units via (pentaphenyl)phenyl units gives rise to dendritic polychromophores (Angew. Chem. 114, 1980-1984 (2002)).

However, preference is given in accordance with the invention to polychromophores of the general formula Ib (referred to below as “terrylene dyes Ib”)

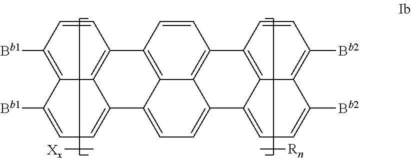

in which the variables are each defined as follows:
B^{b1} are joined together with formation of a six-membered ring to give a radical of the formula (a) or (d)

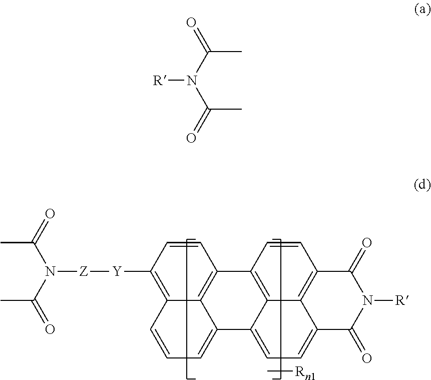

or one radical is hydrogen and the other radical an X radical;
B^{b2} are joined together with formation of a six-membered ring to give a radical of the formula (a) when the B^{b1} radicals together are a radical of the formula (a);
   are joined together with formation of a six-membered ring to give a radical of the formula (a) when one B^{b1} radical is hydrogen and the other radical is an X radical, where: x=0 and n≠0;
   are joined together with formation of a six-membered ring to give a radical of the formula (d) when the B^{b1} radicals together are a radical of the formula (a) or (d) or one B^{b1} radical is hydrogen and the other radical is an X or R radical, where: x=0 and n≠0;
R is aryloxy, arylthio, hetaryloxy or hetarylthio, to each of which may be fused further saturated or unsaturated 5- to 7-membered rings whose carbon skeleton may be interrupted by one or more —O—, —S—, —NR¹—, —N═CR¹—, —CO—, —SO— and/or —SO₂— moieties, where the entire ring system may be mono- or polysubstituted by the (i), (ii), (iii), (iv) and/or (v) radicals:
   (i) C₁-C₃₀-alkyl whose carbon chain may be interrupted by one or more —O—, —S—, —NR¹—, —N═CR¹—, —C≡C—, —CR¹═CR¹—, —CO—, —SO— and/or —SO₂— moieties and which may be mono- or polysubstituted by: C₁-C₁₂-alkoxy, C₁-C₆-alkylthio, —C≡CR¹, —CR¹═CR¹₂, hydroxyl, mercapto, halogen, cyano, nitro, —NR²R³, —NR²COR³, —CONR²R³, —SO₂NR²R³, —COOR², —SO₃R², aryl and/or saturated or unsaturated C₄-C₇-cycloalkyl whose carbon skeleton may be interrupted by one or more —O—, —S—, —NR¹—, —N═CR¹—, —CR¹═CR¹—, —CO—, —SO— and/or —SO₂— moieties, where the aryl and cycloalkyl radicals may each be mono- or polysubstituted by C₁-C₁₈-alkyl and/or the above radicals specified as substituents for alkyl;
   (ii) C₃-C₈-cycloalkyl whose carbon skeleton may be interrupted by one or more —O—, —S—, —NR¹—, —N═CR¹—, —CR¹═CR¹—, —CO—, —SO— and/or —SO₂— moieties and to which may be fused further saturated or unsaturated 5- to 7-membered rings whose carbon skeleton may be interrupted by one or more —O—, —S—, —NR¹—, —N═CR¹—, —CR¹═CR¹—, —CO—, —SO— and/or —SO₂— moieties, where the entire ring system may be mono- or polysubstituted by:
   C₁-C₁₈-alkyl, C₁-C₁₂-alkoxy, C₁-C₆-alkylthio, —C≡C¹, —CR¹═CR¹₂, hydroxyl, mercapto, halogen, cyano, nitro, —NR²R³, —NR²COR³, —CONR²R³, —SO₂NR²R³, —COOR² and/or —SO₃R²;
   (iii) aryl or hetaryl, to which may be fused further saturated or unsaturated 5- to 7-membered rings whose carbon skeleton may be interrupted by one or more —O—, —S—, —NR¹—, —N═CR¹—, —CR¹═CR¹—, —CO—, —SO— and/or —SO₂— moieties, where the entire ring system may be mono- or polysubstituted by:
   C₁-C₁₈-alkyl, C₁-C₁₂-alkoxy, C₁-C₆-alkylthio, —C≡CR¹, —CR¹═CR¹₂, hydroxyl, mercapto, halogen, cyano, nitro, —NR²R³, —NR²COR³, —CONR²R³, —SO₂NR²R³, —COOR², —SO₃R², aryl and/or hetaryl, each of which may be mono- or polysubstituted by C₁-C₁₈-alkyl, C₁-C₁₂-alkoxy, hydroxyl, mercapto, halogen, cyano, nitro, —NR²R³, —NR²COR³, —CONR²R³, —SO₂NR²R³, —COOR² and/or —SO₃R²;
   (iv) a -U-aryl radical which may be mono- or polysubstituted by the above radicals specified as substituents for the aryl radicals (iii), where U is an —O—, —S—, —NR¹—, —CO—, —SO— or —SO₂— moiety;
   (v) C₁-C₁₂-alkoxy, C₁-C₆-alkylthio, —C≡C¹, —CR¹═CR¹₂, hydroxyl, mercapto, halogen, cyano, nitro, —NR²R³, —NR²COR³, —CONR²R³, —SO₂NR²R³, —COOR² or —SO₃R²,
   where the R radicals may be the same or different when n>1;
R¹ is hydrogen or C₁-C₁₈-alkyl, where the R¹ radicals may be the same or different when they occur more than once;
R², R³ are each independently hydrogen;
   C₁-C₁₈-alkyl whose carbon chain may be interrupted by one or more —O—, —S—, —CO—, —SO— and/or —SO₂— moieties and which may be mono- or polysubstituted by C₁-C₁₂-alkoxy, C₁-C₆-alkylthio, hydroxyl, mercapto, halogen, cyano, nitro and/or —COOR¹;
   aryl or hetaryl, to each of which may be fused further saturated or unsaturated 5- to 7-membered rings whose carbon skeleton may be interrupted by one or more —O—, —S—, —CO— and/or —SO₂— moieties, where the entire ring system may be mono- or polysubstituted by C₁-C₁₂-alkyl and/or the above radicals specified as substituents for alkyl;
X is a perylenedicarboximide radical of the formula

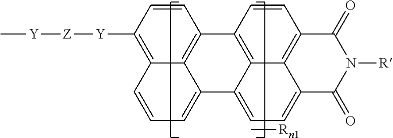

R′ is C₄-C₃₀-alkyl whose carbon chain may be interrupted by one or more —O—, —S—, —NR¹—, —N═CR¹—, —C≡C—, —CR¹═CR¹—, —CO—, —SO— and/or —SO₂— moieties and which may be mono- or polysubstituted by the (ii), (iii), (iv) and/or (v) radicals specified as substituents for the R radicals;
   C₃-C₈-cycloalkyl to which may be fused further saturated or unsaturated 5- to 7-membered rings whose carbon skeleton may be interrupted by one or more —O—, —S—, —NR¹—, —N═CR¹—, —CR¹═CR¹—, —CO—, —SO— and/or —SO₂— moieties, where the entire ring system may be mono- or polysubstituted by the (i), (ii), (iii), (iv) and/or (v) radicals specified as substituents for the R radicals;
   aryl or hetaryl, to each of which may be fused further saturated or unsaturated 5- to 7-membered rings whose carbon skeleton may be interrupted by one or more —O—, —S—, —NR¹—, —N═CR¹—, —CR¹═CR¹—, —CO—, —SO— and/or —SO₂— moieties, where the entire ring system may be mono- or polysubstituted by the (i), (ii), (iii), (iv), (v) radicals specified as substituents for the R radicals, and/or aryl- and/or hetarylazo, each of which may be mono- or polysubstituted by C₁-C₁₀-alkyl, C₁-C₆-alkoxy and/or cyano;
Y is —O—or —S—;
Z is a bridging member having at least one aromatic or heteroaromatic radical, where the Y groups are bonded to the aromatic or heteroaromatic radical;
x is from 2 to 6 when the B^{b1} and B^{b2} radicals are each a radical of the formula (a);
   is 0 for all further definitions of the B^{b1} and B^{b2} radicals;
n is from 0 to 8, where x+n≦8 and n≠0 when x=0;
n1 is from 0 to 2.

The terrylene dyes Ib and their preparation are described in the prior German patent application 10 2005 037 115.9.

In the terrylene dyes Ib, the perylene chromophores are bonded via the —Y—Z—Y— moiety directly to the ring skeleton of the terrylene chromophore and/or via the —Z—Y— moiety to the imide nitrogen atoms of the terrylene chromophore.

The joining bridging member Z has at least one aromatic or hetaromatic radical to which Y and the imide nitrogen atom are bonded.

Z is preferably an arylene or hetarylene radical of the formulae

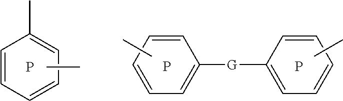

in which the rings P may be the same or different, may comprise heteroatoms as ring atoms and/or may have fused 5- to 7-membered rings whose carbon skeleton may be interrupted by one or more —O—, —S—, —NR¹—, —N═CR¹—, —CR¹═CR¹—, —CO—, —SO— and/or —SO₂— moieties, where the entire ring system may be mono- or polysubstituted by the (i), (ii), (iii) and/or (v) radicals specified as substituents for the R radicals.

G is:

a chemical bond;

an —O—, —S—, —NR¹—, —N═CR¹—, —C≡C—, —CR¹═CR¹—, —CO—, —SO— or —SO₂— moiety or C₁-C₁₂-alkylene or C₄-C₇-cycloalkylene whose carbon chain may in each case be interrupted once or more than once by these moieties and which may each be mono- or polysubstituted by the (i), (ii), (iii) and/or (v) radicals specified as substituents for the R radicals; arylene or hetarylene, each of which may likewise be mono- or polysubstituted by the (i), (ii), (iii) and/or (v) radicals, hydroxyl and mercapto being excluded as (v) radicals.

Particularly preferred bridging members Z are arylene radicals of the formulae

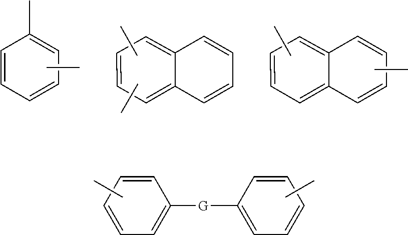

in which the phenylene or naphthylene rings may be mono- or polysubstituted by C₁-C₁₈-alkyl and G is a chemical bond, methylene or isopropylene.

Specific examples of particularly preferred bridging members Z are:

1,4-, 1,3- and 1,2-phenylene, 1,4-[2,5-di(tert-butyl)]phenylene, 1,4-(2,5-dihexyl)-phenylene, 1,4-[2,5-di(tert-octyl)]phenylene, 1,4-(2,5-didodecyl)phenylene, 1,4-[2,5-di(2-dodecyl)]phenylene,1,4- and 1,8-naphthylene, 4,4′-, 3,3′- and 2,2′-biphenylene, 4,4′-di(2,2′,6,6′-tetramethyl)phenylene, 4,4′-di(2,2′,6,6′-tetraethyl)phenylene, 4,4′-di(2,2′,6,6′-tetraisopropyl)phenylene, 4,4′-di(2,2′,6,6′-tetrahexyl)phenylene, 4,4′-di[2,2′,6,6′-tetra(2-hexyl)]phenylene, 4,4′-di[2,2′,6,6′-tetra(tert-octyl)]phenylene, 4,4′-di(2,2′,6,6′-tetradodecyl)phenylene and 4,4′-di[2,2′,6,6′-tetra(2-dodecyl)]phenylene and

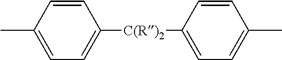

where R″ is hydrogen, methyl, ethyl or phenyl.

Very particularly preferred bridging members Z are 1,4-phenylene and 4,4′-di(2,2′,6,6′-tetramethyl)phenylene.

Like the terrylene dyes Ia, the terrylene dyes Ib may additionally be substituted by (het)aryloxy and (het)arylthio radicals R.

R and also the further variables occurring in formula Ib are each as defined in formula Ia. The same preferences also apply.

The advantage of the fluorescence conversion solar cells comprising inventive fluorescent dyes based on terrylene is that the incident sunlight can be converted to long-wavelength NIR radiation and hence to radiation adjusted particularly appropriately to silicon photovoltaic cells. Thus, the terrylene dyes Ia absorb at from about 480 to 770 nm and emit at from about 650 to 850 nm. In the case of the terrylene dyes Ib, the absorption range is extended up to about 400 nm at the short-wavelength end and distinctly enhanced compared to the terrylene dyes Ia in the range from 400 to 600 nm.

Particularly efficient conversion of sunlight can be achieved when the terrylene dyes are combined in combination with fluorescent dyes absorbing and emitting at shorter wavelength, in particular in the form of a dye cascade.

Suitable fluorescent dyes for this dye combination are especially those from the group of the perylenecarboxylic acid derivatives, naphthalenecarboxylic acid derivatives and (iso)violanthrone derivatives, preference being given to the combination with fluorescent dyes based on perylene.

Suitable fluorescent dyes based on perylenecarboxylic acid derivatives (referred to as “perylene dyes” below) are, for example, the perylenetetracarboximides, perylenetetracarboxylic monoanhydride monoimides, peryleneteetracarboxylic dianhydrides, perylenedicarboximides, perylene-3,4-dicarboxylic anhydrides, perylenedicarboxylic esters, perylenedicarboxamides and polychromophores which have perylene units but do not comprise any terrylene units, preference being given to the perylenedicarboxylic esters, particular preference to the perylenedicarboximides and very particular preference to the perylenetetracarboximides.

The perylenediarboximides derive from perylene-3,4-dicarboxylic acid and the perylenedicarboxylic esters and -dicarboxamides from the isomeric perylene-3,9- and -3,10-dicarboxylic acids.

In the case of the perylenecarboximides, the R′ radicals are particularly suitable substituents on the imide nitrogen atom, as is the case for the terrylene dyes. The same preferences also apply.

Like the terrylene dyes la, the perylene dyes may be unsubstituted. However, they are preferably substituted by from 1 to 5 (in particular from 2 to 4 in the case of the perylenetetracarboximides) (het)aryloxy or (het)arylthio radicals R.

The perylene dyes may also be substituted by cyano groups. This substitution has particular significance for perylenedicarboximides and perylenedicarboxylic esters.

Examples of particularly suitable perylene dyes include:

N,N′-Bis(2,6-diisopropylphenyl)perylene-3,4:9,10-tetracarboximide, N,N′-bis(2,6-dimethylphenyl)perylene-3,4:9,10-tetracarboximide, N,N′-bis(7-tridecyl)perylene-3,4:9,10-tetracarboximide, N,N′-bis(2,6-diisopropylphenyl)-1,6,7,12-tetra(4-tert-octyl-phenoxy)perylene-3,4:9,10-tetracarboximide, N,N′-bis(2,6-diisopropylphenyl)-1,6,7,12-tetraphenoxyperylene-3,4:9,10-tetracarboximide, N,N′-bis(2,6-diisopropylphenyl)-1,6- and -1,7-bis(4-tert-octylphenoxy)perylene-3,4:9,10-tetracarboximide, N,N′-bis(2,6-diisopropylphenyl)-1,6- and -1,7-bis(2,6-diisopropylphenoxy)perylene-3,4:9,10-tetracarboximide, N-(2,6-diisopropylphenyl)perylene-3,4-dicarboximide, N-(2,6-diisopropylphenyl)-9-phenoxyperylene-3,4-dicarboximide, N-(2,6-diisopropylphenyl)-9-(2,6-diisopropylphenoxy)perylene-3,4-dicarboximide, N-(2,6-diisopropylphenyl)-9-cyanoperylene-3,4-dicarboximide, N-(7-tridecyl)-9-phenoxyperylene-3,4-dicarboximide, diisobutyl perylene-3,9- and -3,10-dicarboxylate, diisobutyl 4,10-dicyanoperylene-3,9- and 4,9-dicyanoperylene-3,10-dicarboxylate and N-(2,6-diisopropylphenyl)-perylene-3,9- and -3,10-dicarboxamide.

The polychromophores based on perylene are preferably, analogously to the polychromophoric terrylene dyes Ib, constructed from a central perylene chromophore and naphthalimide chromophores bonded thereto. The naphthalimide chromophores may be bonded via the —Y—Z—Y— moiety directly to the ring skeleton of the perylene chromophore (from 2 to 4 naphthalimides) and/or via the —Z—Y— moiety to the imide nitrogen atoms of a central perylenetetracarboximide, to the amide nitrogen atoms of a central perylenedicarboxamide or to the hydroxyl oxygen atoms of a central perylene-3,9/3,10-dicarboxylic acid (esterification).

The perylene chromophore may likewise additionally be substituted by (het)aryloxy or (het)arylthio radicals R. In the case of the polychromophores based on ester, substitution by halogen or cyano in the 4,10/4,9-positions is also possible.

The perylene dyes are common knowledge or described in the prior German patent applications 10 2005 032 583.1 (substitution with ortho,ortho′-disubstituted (thio)phenoxy radicals R) and 10 2005 037 115.9 (polychromophores).

They typically absorb in the wavelength range of from 360 to 630 nm and emit at from about 470 to 750 nm. In the case of the polychromophoric perylene dyes, the absorption extends up to in the region of about 300 nm.

The combination of terrylene and perylene dyes thus allows sunlight to be absorbed within the range from 360 to 770 nm and to be converted to NIR radiation.

Suitable for this combination are not only the perylene dyes themselves, but also fluorescent dyes with related structures, especially those based on violanthrones and isoviolanthrones, as described in EP-A-073 007.

Particularly suitable examples include alkoxylated violanthrones and isoviolanthrones such as 6,15-didodecyloxyisoviolanthrenedione-(9,18).

Finally, it is also possible to use fluorescent dyes based on naphthalenecarboxylic acid derivatives in combination with the terrylene dyes and, if desired, perylene dyes and/or (iso)violanthrones.

The fluorescent dyes based on naphthalene absorb in the UV region at wavelengths of from about 300 to 420 nm and emit at from about 380 to 520 nm. They not only bring about conversion of the UV light to longer-wavelength light but in particular also form effective UV protection for the inventive fluorescence conversion solar cells.

In the case of the naphthalenecarboxylic acid derivatives too, preference is given to the imides, i.e. to the naphthalene-1,8:4,5-tetracarboximides and especially the naphthalene-1,8-dicarboximides (referred to below as “naphthalimides” for short).

The naphthalimides, especially the naphthalene-1,8:4,5-tetracarboximides, may likewise be unsubstituted in the naphthalene skeleton. However, the naphthalene-dicarboximides in particular preferably bear one or preferably two alkoxy, aryloxy or cyano groups as substituents.

The alkoxy groups have in particular from 1 to 24 carbon atoms. In the case of the aryloxy groups, preference is given to phenoxy radicals which may be unsubstituted or substituted.

Examples of particularly suitable naphthalimides include:

N-(2-Ethylhexyl)-4,5-dimethoxynaphthalene-1,8-dicarboximide, N-(2,6-diisopropyl-phenyl)-4,5-dimethoxynaphthalene-1,8-dicarboximide, N-(7-tridecyl)-4,5-dimethoxy-naphthalene-1,8-dicarboximide, N-(2,6-diisopropylphenyl)-4,5-diphenoxynaphthalene-1,8-dicarboximide and N,N′-bis(2,6-diisopropylphenyl)-1,8:4,5-naphthalenetetracarboximide.

The concentration of the fluorescent dyes is preferably adjusted such that the absorbance over the layer thickness of the polymer panel doped with the particular fluorescent dye is close to 1 over a maximum spectral region, and is hence dependent upon the dimensions of the polymer panels, which may be from about 5 to 100 cm, preferably from 5 to 30 cm, in length and width, and from about 1 to 20 mm, preferably from 1 to 10 nm, in thickness.

Accordingly, the dye concentration in the particular polymer panel is typically from 10 to 20 000 ppm, preferably from 50 to 1000 ppm and more preferably from 100 to 500 ppm.

In the case of polymer-coated glass panels, the concentration of the fluorescent dye in the polymer coating is typically about 10 000 ppm; the thickness of the polymer coating is typically from about 100 to 300 μm.

The polymer panels doped with the fluorescent dyes or the polymer coating which comprises the fluorescent dyes and has been applied to the glass panels consists preferably of colorless transparent thermoplastic polymers.

Examples of preferred thermoplastic polymers are acrylic resins, styrene polymers, polycarbonates, polyamides, polyesters, thermoplastic polyurethanes, polyethersulfones, polysulfones, vinyl polymers or mixtures thereof, the acrylic resins and the polycarbonates being particularly suitable.

Suitable acrylic resins include the polyalkyl and/or -aryl esters of (meth)acrylic acid, poly(meth)acrylamides and poly(meth)acrylonitrile. Preferred acrylic resins are polyalkyl methacrylates such as polymethyl methacrylate (PMMA) and polyethyl methacrylate (PEMA), including in impact-modified form, particular preference being given to PMMA and impact-modified PMMA (HI (high impact)-PMMA). The PMMA preferably comprises a content of generally not more than 20% by weight of (meth)acrylate comonomers such as n-butyl (meth)acrylate or methyl acrylate. HI-PMMA has been impact-modified by suitable additives. Useful impact modifiers include, for example, EPDM rubbers, polybutyl acrylates, polybutadiene, polysiloxanes or methacrylate/butadiene/styrene (MBS) and methacrylate/acrylonitrile/butadiene/styrene copolymers. Suitable impact-modified PMMAs are described, for example, by M. Stickler, T. Rhein in Ullmann's encyclopedia of industrial chemistry Vol. A21, pages 473-486, VCH Publishers Weinheim, 1992, and H. Domininghaus, Die Kunststoffe and ihre Eigenschaften [The polymers and their properties], VDI-Verlag Dusseldorf, 1992. Suitable polymethyl methacrylates are otherwise known to those skilled in the art and are obtainable, for example, under the trademarks Altuglas® (Arkema) and Plexiglas® (Röhm).

Useful styrene polymers include all (co)polymers which are constructed fully or partly from vinylaromatic compounds. Suitable vinylaromatic compounds are, for example, styrene and styrene derivatives such as mono- or poly-alkyl- and/or -halogen-substituted styrene, and also corresponding naphthyl compounds. Preference is given to employing styrene copolymers. These include, for example, graft copolymers of acrylonitrile and styrene on butadiene rubbers, also known as ABS polymers (e.g. Terluran® (BASF)), graft copolymers of styrene and acrylonitrile on polyalkyl acrylate rubbers, also known as ASA polymers (e.g. Luran® S (BASF)), or styrene-acrylonitrile copolymers, also known as SAN copolymers (e.g. Luran® (BASF)).

Suitable polycarbonates are known per se. In the context of the invention, polycarbonates also include copolycarbonates. The (co)polycarbonates preferably have a molecular weight (weight-average M_{w}, determined by means of gel permeation chromatography in tetrahydrofuran against polystyrene standards) in the range from 10 000 to 200 000 g/mol. M_{w}, is preferably in the range from 15 000 to 100 000 g/mol. This corresponds to relative solution viscosities in the range from 1.1 to 1.5, preferably of from 1.15 to 1.33, measured in each case in 0.5% by weight solution in dichloromethane at 25° C.

Polycarbonates are obtainable, for example, by interface polycondensation according to the processes of DE-C-1 300 266 or by reaction of diphenyl carbonate with bisphenols according to the process of DE-A-14 95 730. Preferred bisphenol is 2,2-di(4-hydroxyphenyl)propane, usually known as bisphenol A.

Instead of bisphenol A, it is also possible to use other aromatic dihydroxyl compounds, especially 2,2-di(4-hydroxyphenyl)pentane, 2,6-dihydroxynaphthalene, 4,4′-dihydroxydiphenyl sulfane, 4,4′-dihydroxydiphenyl ether, 4,4′-dihydroxydiphenyl sulfite, 4,4′-dihydroxydiphenylmethane, 1,1-di(4-hydroxyphenyl)ethane, 4,4-dihydroxydiphenyl or dihydroxydiphenylcycloalkanes, preferably dihydroxydiphenylcyclohexanes or dihydroxycyclopentanes, especially 1,1-bis(4-hydroxyphenyl)-3,3,5-trimethylcyclo-hexane, and also mixtures of the aforementioned dihydroxyl compounds.

Particularly preferred polycarbonates are those based on bisphenol A or bisphenol A together with up to 80 mol % of the aforementioned aromatic dihydroxyl compounds.

It is also possible to use copolycarbonates according to U.S. Pat. No. 3,737,409. Of particular interest are copolycarbonates based on bisphenol A and bis(3,5-dimethyl-4-hydroxy-phenyl)sulfone and/or 1,1-bis(4-hydroxyphenyl)-3,3,5-trimethylcyclohexyl, which feature high heat deformation resistance.

Commercially available examples are the polycarbonates Makrolon® (Bayer) and Lexan® (GE Plastics).

Suitable polyamides (PA) may be polycondensation products of diamines and dicarboxylic acids, for example adipic acid and hexamethylenediamine, or of amino acids, for example aminoundecanoic acid, or be prepared by ring-opening polymerization of lactams, for example caprolactam or laurolactam. Examples include Ultramid® (BASF), Zytel® and Minion® (Du Pont), Sniamid®, Technyl® and Amodel® (Nyltech), Durethan® (Bayer), Akulon® and Stanyl® (DSM), Grilon®, Grilamid® and Grivory® (EMS), Orgamid® and Rilsan® (Atochem) and Nivionplast® (Enichem).

The polyamides used may also be mixtures of polyamides and polyethylene ionomers, for example ethene/methacrylic acid copolymers comprising, for example, sodium, zinc and/or lithium counterions (e.g. Surlyn® (DuPont)).

Suitable polyesters are the relatively high to high molecular weight esterification products of dibasic acids, especially terephthalic acid, with dihydric alcohols, in particular ethylene glycol. Among the polyalkylene terephthalates, polyethylene terephthalate (PET; Arnite® (Akzo), Grilpet® (EMS-Chemie), Valox® (GEP)) is particularly suitable.

Finally, thermoplastic polyurethanes (TPUs) are the reaction products of diisocyanates and long-chain diols. Compared to the polyurethane foams formed from polyisocyanates (comprising at least three isocyanate groups) and polyhydric alcohols (comprising at least three hydroxyl groups, especially polyether polyols and polyester polyols, thermoplastic polyurethanes have only minor crosslinking, if any, and accordingly have a linear structure. Thermoplastic polyurethanes are sufficiently well known to those skilled in the art and a description can be found, for example, in Kuntstoff-Handbuch [Plastics handbook], Volume 7, Polyurethanes, ed. G. Oertel, 2nd ed., Carl Hanser Verlag, Munich, 1983, especially on pages 428-473. An example of a commercially available product is Elastolan® (Elastogran).

The polymer classes of the polyether sulfones and polysulfones are likewise known to those skilled in the art and are commercially available under the trade names Ultrason® E and Ultrason® S (BASF).

Finally, an example of a suitable vinyl polymer is polyvinyl chloride (PVC).

If desired, the polymer material may additionally comprise stabilizing additives.

Particularly suitable additives are light stabilizers (UV-A and/or UV-B absorbers) and oxidation stabilizers.

These additives are preferably colorless or have only low intrinsic coloration (only low absorption, if any, in the visible region). High migration fastness and thermal stability are further preferred properties of these additives.

Examples of suitable light stabilizers include the known classes of the sterically hindered amines, the benzophenones and the benzotriazoles.

The light stabilizers based on sterically hindered amines (HALS) comprise, as the essential unit, a 2,6-dialkyl-substituted, especially a 2,6-dimethyl-substituted, piperidine which is bonded in the 4-position to further piperidine units via a wide variety of bridge members. The additives from this group simultaneously act as antioxidants. Examples of particularly suitable commercial products are Tinuvin® 123, 571, 770, 765 and 622 (Ciba).

The light stabilizers based on benzophenone are 2-hydroxy- and 2,2′-dihydroxy-benzophenone which may be substituted by further hydroxyl or alkoxy groups. A particularly suitable example is the commercial product Uvinul® 3008 (BASF).

The light stabilizers based on benzotriazole bear, on the internal nitrogen atom, a 2-hydroxyphenyl radical which may be substituted in the 5- and, if appropriate, also in the 3-position by preferably tertiary alkyl groups. Examples of particularly suitable commercial products are Tinuvin® P, 571, 350 and 234 (Ciba), and also Cyasorb® UV 5411 (Cytec).

Examples of suitable oxidation stabilizers include the known classes of the sterically hindered phenols and the phosphites and phosphonites.

The oxidation stabilizers based on sterically hindered phenols comprise, as the essential unit, a phenol substituted by at least one tert-butyl group in the ortho-position, especially by tert-butyl groups in both ortho-positions, to the OH group. Most known products comprise a plurality of these units which are bonded to one another via various bridge members. Particularly suitable commercial products of this class are, for example, Irganox® 1076, 1010 and 245 (Ciba).

The oxidation stabilizers based on phosphites and phosphonites are typically the esters of the corresponding phosphoric esters with alkyl-substituted, especially tert-butyl-substituted, phenols. Particularly suitable commercial products include Irgaphos® 168 and P-EPQ (Ciba).

When such additives are used in the inventive fluorescence conversion solar cells, their use amount is typically from 500 to 5000 ppm, preferably from 1000 to 3000 ppm, based on the polymer matrix.

The polymer panels comprising the fluorescent dyes may be produced in various ways. For example, PMMA panels may be obtained by the casting process or by extrusion. Extrusion is also the preferred process for the preparation of polycarbonate panels.

Glass panels coated with the fluorescent dye-containing polymer may likewise be obtained by known methods. In these methods, a polymer solution is applied to the glass panel, for example with a doctor blade, and subsequently dried.

### EXAMPLE

First, two PMMA panels doped with different fluorescent dyes were produced by the casting process.

To this end, in each case 1 kg of a PMMA prepolymer in the form of a 10% by weight solution in MMA was admixed at 10° C. with 8 g of azobisisobutyronitrile, (1) 300 ppm of N,N′-bis(2,6-diisopropylphenyl)-1,6,7,12-tetraphenoxyperylene-3,4:9,10-tetracarboximide and 300 ppm of N-(2,6-diisopropylphenyl)-9-cyanoperylene-3,4:9,10-dicarboximide or (2) 120 ppm of N,N′-bis(2,6-diisopropylphenyl)-1,6,9,14-tetra(2,6-diisopropylphenoxy)terrylene-3,4:11,12-tetracarboximide. The mixture was stirred at 10° C. until all constituents had dissolved (about 3 h). The resulting solution was injection-molded between two plane-parallel silicate glass panels (50 cm×40 cm) and a 0.2 cm-thick spacer sealing the cavity between the silicate panels. The casting was placed into a waterbath at 70° C. for 2 h and the polymerization was then completed by storing it at 110° C. for a further 0.5 h. After complete cooling, a 5 cm×10 cm panel was sawn out of the resulting panel and its edges were polished.

Subsequently, the sawn-out PMMA panels were connected to silicon photovoltaic cells and converted to fluorescence conversion solar cells.

First, only the optoelectric cell efficiency n of the PMMA panel (1) was determined. To this end, two silicon cells of dimensions 47 mm×1 mm were adhesive-bonded on a long edge of the PMMA panel (1) with an epoxy resin. The efficiency η was then determined with an IEPC scanner from Aescusoft under irradiation with AM 1.5 light (1000 W) at 25° C. Extrapolation to the coverage of all panel edges with silicon cells gave an η value of 2.1%. From an outdoor measurement of short-circuit current and terminal voltage under blue sky, an efficiency η of 2.7% was determined with the known filling factor of the silicon cells.

The PMMA panel (1) was then, while establishing a 0.1 mm-thick air gap, placed above the PMMA panel (2) which comprises the terrylene dye and has been equipped analogously with two silicon cells. The panel stack was irradiated as described above, with the PMMA panel (1) pointing toward the light source. Compared to the PMMA panel (1), the panel stack exhibited an efficiency increased by 0.3%.

What is claimed is:

1. A fluorescence conversion solar cell based on one or more panels composed of polymer doped with at least one fluorescent dye and/or glass panels coated with the doped polymer and photovoltaic cells mounted on the edges of the panels, which comprise one or more fluorescent dyes based on terrylenecarboxylic acid derivatives or a combination of these fluorescent dyes with further fluorescent dyes.

2. The fluorescence conversion solar cell according to claim 1, which comprises at least one fluorescent dye from the group of the terrylenetetracarboximides, terrylenetetracarboxylic monoanhydride monoimides, terrylenetetracarboxylic dianhydrides, terrylenedicarboximides, terrylenedicarboxylic anhydrides, condensation products of terrylenetetra- and -dicarboxylic anhydrides with aromatic diamines and polychromophores having terrylene units.

3. The fluorescence conversion solar cell according to claim 1 or 2, which comprises at least one fluorescent dye which is based on terrylenecarboxylic acid derivatives and emits in the NIR in combination with at least one fluorescent dye which absorbs and emits at shorter wavelength.

4. The fluorescence conversion solar cell according to claims 1 to 3, which comprises at least one fluorescent dye of the general formula la 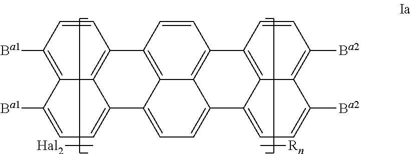
in which the variables are each defined as follows:
B^{a1} are joined together with formation of a six-membered ring to give a radical of the formula (a), (b) or (c) 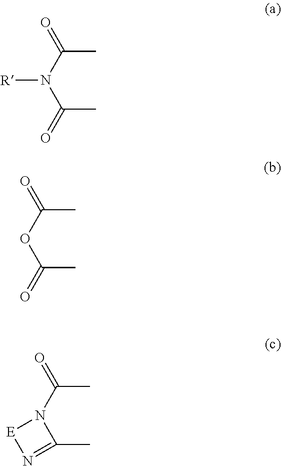
both are hydrogen or a —COOM radical or
one of the two radicals is an R radical or bromine and the other radical is hydrogen;
B^{a2}, independently of B^{a1}, are joined together with formation of a six-membered ring to give a radical of the formula (a), (b) or (c), or are both a —COOM radical;
R is aryloxy, arylthio, hetaryloxy or hetarylthio, to each of which may be fused further saturated or unsaturated 5- to 7-membered rings whose carbon skeleton may be interrupted by one or more —O—, —S—, —NR¹—, —N—CR¹—, —CO—, —SO— and/or —SO₂— moieties, where the entire ring system may be mono- or polysubstituted by the (i), (ii), (iii), (iv) and/or (v) radicals:
(i) C₁-C₃₀-alkyl whose carbon chain may be interrupted by one or more —O—, —S—, —NR¹—, —N═CR¹—, —C≡C—, —CR¹═CR¹—, —CO—, —SO— and/or —SO₂— moieties and which may be mono- or polysubstituted by: C₁-C₁₂-alkoxy, C₁-C₆-alkylthio, —C≡CR¹, —CR¹═CR¹₂, hydroxyl, mercapto, halogen, cyano, nitro, —NR²R³, —NR²COR³, —CONR²R³, —SO₂NR²R³, —COOR², —SO₃R², aryl and/or saturated or unsaturated C₄-C₇-cycloalkyl whose carbon skeleton may be interrupted by one or more —O—, —S—, —NR¹—, —N═CR¹—, —CR¹═CR¹—, —CO—, —SO— and/or —SO₂— moieties, where the aryl and cycloalkyl radicals may each be mono- or polysubstituted by C₁-C₁₈-alkyl and/or the above radicals specified as substituents for alkyl;
(ii) C₃-C₈-cycloalkyl whose carbon skeleton may be interrupted by one or more —O—, —S—, —NR¹—, —N═CR¹—, —CR¹═CR¹—, —CO—, —SO— and/or —SO₂— moieties and to which may be fused further saturated or unsaturated 5- to 7-membered rings whose carbon skeleton may be interrupted by one or more —O—, —S—, —NR¹—, —N═CR¹—, —CR¹═CR¹—, —CO—, —SO— and/or —SO₂— moieties, where the entire ring system may be mono- or polysubstituted by: C₁-C₁₈-alkyl, C₁-C₁₂-alkoxy, C₁-C₆-alkylthio, —C≡CR¹, —CR¹═CR¹₂, hydroxyl, mercapto, halogen, cyano, nitro, —NR²R³, —NR²COR³, —CONR²R³, —SO₂NR²R³, —COOR² and/or —SO₃R²;
(iii) aryl or hetaryl, to each of which may be fused further saturated or unsaturated 5- to 7-membered rings whose carbon skeleton may be interrupted by one or more —O—, —S—, —NR¹—, —N═CR¹—, —CR¹═CR¹—, —CO—, —SO— and/or —SO₂— moieties, where the entire ring system may be mono- or polysubstituted by: C₁-C₁₈-alkyl, C₁-C₁₂-alkoxy, C₁-C₆alkylthio, —C≡CR¹, —CR¹═CR¹₂, hydroxyl, mercapto, halogen, cyano, nitro, —NR²R³, —NR²COR³, —CONR²R³, —SO₂NR²R³, —COOR², —SO₃R², aryl and/or hetaryl, each of which may be mono- or polysubstituted by C₁-C₁₈-alkyl, C₁-C₁₂-alkoxy, hydroxyl, mercapto, halogen, cyano, nitro, —NR²R³, —NR²COR³, —CONR²R³, —SO₂NR²R³, —COOR² and/or —SO₃R²;
(iv) a -U-aryl radical which may be mono- or polysubstituted by the above radicals specified as substituents for the aryl radicals (iii), where U is an —O—, —S—, —NR¹—, —CO—, —SO— or —SO₂— moiety;
(v) C₁-C₁₂-alkoxy, C₁-C₆-alkylthio, —C≡CR¹, —CR¹═CR¹₂, hydroxyl, mercapto, halogen, cyano, nitro, —NR²R³, —NR²COR³, —CONR²R³, —SO₂NR²R³, —COOR² or —SO₃R²,
where the R radicals may be the same or different when n>1;
R¹ is hydrogen or C₁-C₁₈-alkyl, where the R¹ radicals may be the same or different when they occur more than once;
R², R³ are each independently hydrogen;
C₁-C₁₈-alkyl whose carbon chain may be interrupted by one or more —O—, —S—, —CO—, —SO— and/or —SO₂— moieties and which may be mono- or poly-substituted by C₁-C₁₂-alkoxy, C₁-C₆-alkylthio, hydroxyl, mercapto, halogen, cyano, nitro and/or —COOR¹;
aryl or hetaryl, to each of which may be fused further saturated or unsaturated 5- to 7-membered rings whose carbon skeleton may be interrupted by one or more —O—, —S—, —CO— and/or —SO₂— moieties, where the entire ring system may be mono- or polysubstituted by C₁-C₁₂-alkyl and/or the above radicals specified as substituents for alkyl;
Hal is bromine or cyano;
R′ is C₄-C₃₀-alkyl whose carbon chain may be interrupted by one or more —O—, —S—, —NR¹—, —N═CR¹—, —C≡C—, —CR¹═CR¹—, —CO—, —SO— and/or —SO₂— moieties and which may be mono- or polysubstituted by the (ii), (iii), (iv) and/or (v) radicals specified as substituents for the R radicals;
C₃-C₈-cycloalkyl to which may be fused further saturated or unsaturated 5- to 7-membered rings whose carbon skeleton may be interrupted by one or more —O—, —S—, —NR¹—, —N═CR¹—, —CR¹═CR¹—, —CO—, —SO— and/or —SO₂— moieties, where the entire ring system may be mono- or polysubstituted by the (i), (ii), (iii), (iv) and/or (v) radicals specified as substituents for the R radicals;
aryl or hetaryl, to each of which may be fused further saturated or unsaturated 5- to 7-membered rings whose carbon skeleton may be interrupted by one or more —O—, —S—, —NR¹—, —N═CR¹—, —CR¹═CR¹—, —CO—, —SO— and/or —SO₂— moieties, where the entire ring system may be mono- or polysubstituted by the (i), (ii), (iii), (iv), (v) radicals specified as substituents for the R radicals, and/or aryl- and/or hetarylazo, each of which may be mono- or polysubstituted by C₁-C₁₀-alkyl, C₁-C₆-alkoxy and/or cyano;
E is 1,2-phenylene, 1,8- or 2,3-naphthylene or 2,3- or 3,4-pyridylene, each of which may be substituted by C₁-C₁₂-alkyl, C₁-C₆-alkoxy, hydroxyl, nitro and/or halogen;
M is hydrogen, alkali metal cation, [NH₄]⁺ or [NR²₄]⁺;
n is from 2 to 6 or else 0 when (1) the B^{a1} and B^{a2} radicals are each a radical of the formula (a) or (2) the B^{a1} radicals are a radical of the formula (a) and the B^{a2} radicals are both hydrogen or one of the two B^{a2} radicals is bromine and the other B^{a2} radical is hydrogen;
z is from 0 to 6, where n+z≦6 and z may only be different from 0 when the B^{a1} and Ba² radicals are each a radical of the formula (a).

5. The fluorescence conversion solar cell according to claims 1 to 3, which comprises at least one fluorescent dye of the general formula Ib 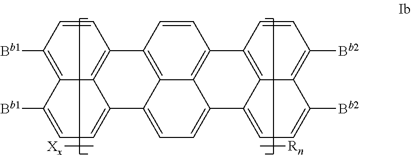
in which the variables are each defined as follows:
B^{b1} are joined together with formation of a six-membered ring to give a radical of the formula (a) or (d) 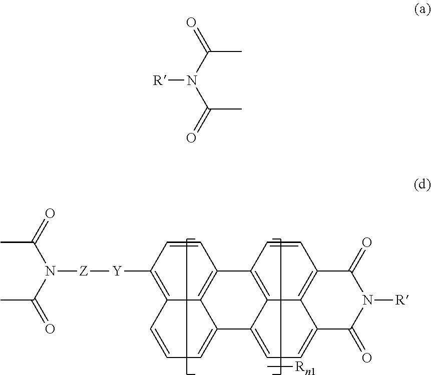
or one radical is hydrogen and the other radical an X radical;
B^{b2} are joined together with formation of a six-membered ring to give a radical of the formula (a) when the B^{b1} radicals together are a radical of the formula (a);
are joined together with formation of a six-membered ring to give a radical of the formula (a) when one B^{b1} radical is hydrogen and the other radical is an X radical, where: x=0 and n≠0;
are joined together with formation of a six-membered ring to give a radical of the formula (d) when the B^{b1} radicals together are a radical of the formula (a) or (d) or one B^{b1} radical is hydrogen and the other radical is an X or R radical, where: x=0 and n≠0;
R is aryloxy, arylthio, hetaryloxy or hetarylthio, to each of which may be fused further saturated or unsaturated 5- to 7-membered rings whose carbon skeleton may be interrupted by one or more —O—, —S—, —NR¹—, —N═CR¹—, —CO—, —SO— and/or —SO₂— moieties, where the entire ring system may be mono- or polysubstituted by the (i), (ii), (iii), (iv) and/or (v) radicals:
(i) C₁-C₃₀-alkyl whose carbon chain may be interrupted by one or more —O—, —S—, —NR¹—, —N═CR¹—, —C≡C—, —CR¹═CR¹—, —CO—, —SO— and/or —SO₂— moieties and which may be mono- or polysubstituted by: C₁-C₁₂-alkoxy, C₁-C₆-alkylthio, —C≡CR¹, —CR¹═CR¹₂, hydroxyl, mercapto, halogen, cyano, nitro, —NR²R³, —NR²COR³, —CONR²R³, —SO₂NR²R³, —COOR², —SO₃R², aryl and/or saturated or unsaturated C₄-C₇-cycloalkyl whose carbon skeleton may be interrupted by one or more —O—, —S—, —NR¹—, —N═CR¹—, —CR¹═CR¹—, —CO—, —SO— and/or —SO₂— moieties, where the aryl and cycloalkyl radicals may each be mono- or polysubstituted by C₁-C₁₈-alkyl and/or the above radicals specified as substituents for alkyl;
(ii) C₃-C₈-cycloalkyl whose carbon skeleton may be interrupted by one or more —O—, —S—, —NR¹—, —N═CR¹—, —CR¹═CR¹—, —CO—, —SO— and/or —SO₂— moieties and to which may be fused further saturated or unsaturated 5- to 7-membered rings whose carbon skeleton may be interrupted by one or more —O—, —S—, —NR¹—, —N═CR¹—, —CR¹═CR¹—, —CO—, —SO— and/or —SO₂— moieties, where the entire ring system may be mono- or polysubstituted by: C₁-C₁₈-alkyl, C₁-C₁₂-alkoxy, C₁-C₆-alkylthio, —≡CR¹, —CR¹═CR¹₂, hydroxyl, mercapto, halogen, cyano, nitro, —NR²R³, —NR²COR³, —CONR²R³, —SO₂NR²R³, —COOR² and/or —SO₃R²;
(iii) aryl or hetaryl, to each of which may be fused further saturated or unsaturated 5- to 7-membered rings whose carbon skeleton may be interrupted by one or more —O—, —S—, —NR¹—, —N═CR¹—, —CR¹═CR¹—, —CO—, —SO— and/or —SO₂— moieties, where the entire ring system may be mono- or polysubstituted by: C₁-C₁₈-alkyl, C₁-C₁₂-alkoxy, C₁-C₆-alkylthio, —C≡CR¹, —CR¹═CR¹₂, hydroxyl, mercapto, halogen, cyano, nitro, —NR²R³, —NR²COR³, —CONR²R³, —SO₂NR²R³, —COOR², —SO₃R², aryl and/or hetaryl, each of which may be mono- or polysubstituted by C₁-C₁₈-alkyl, C₁-C₁₂-alkoxy, hydroxyl, mercapto, halogen, cyano, nitro, —NR²R³, —NR²COR³, —CONR²R³, —SO₂NR²R³, —COOR² and/or —SO₃R²;
(iv) a -U-aryl radical which may be mono- or polysubstituted by the above radicals specified as substituents for the aryl radicals (iii), where U is an —O—, —S—, —NR¹—, —CO—, —SO— or —SO₂— moiety;
(v) C₁-C₁₂-alkoxy, C₁-C₆-alkylthio, —C≡CR¹, —CR¹═CR¹₂, hydroxyl, mercapto, halogen, cyano, nitro, —NR²R³, —NR²COR³, —CONR²R³, —SO₂NR²R³, —COOR² or —SO₃R²,
where the R radicals may be the same or different when n>1;
R¹ is hydrogen or C₁-C₁₈-alkyl, where the R¹ radicals may be the same or different when they occur more than once;
R², R³ are each independently hydrogen;
C₁-C₁₈-alkyl whose carbon chain may be interrupted by one or more —O—, —S—, —CO—, —SO— and/or —SO₂— moieties and which may be mono- or poly-substituted by C₁-C₁₂-alkoxy, C₁-C₆-alkylthio, hydroxyl, mercapto, halogen, cyano, nitro and/or —COOR¹;
aryl or hetaryl, to each of which may be fused further saturated or unsaturated 5- to 7-membered rings whose carbon skeleton may be interrupted by one or more —O—, —S—, —CO— and/or —SO₂— moieties, where the entire ring system may be mono- or polysubstituted by C₁-C₁₂-alkyl and/or the above radicals specified as substituents for alkyl;
X is a perylenedicarboximide radical of the formula 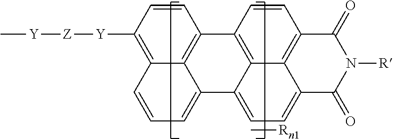
R′ is C₄-C₃₀-alkyl whose carbon chain may be interrupted by one or more —O—, —S—, —NR¹—, —N═CR¹—, —C≡C—, —CR¹═CR¹—, —CO—, —SO— and/or —SO₂— moieties and which may be mono- or polysubstituted by the (ii), (iii), (iv) and/or (v) radicals specified as substituents for the R radicals;
C₃-C₈-cycloalkyl to which may be fused further saturated or unsaturated 5- to 7-membered rings whose carbon skeleton may be interrupted by one or more —O—, —S—, —NR¹—, —N═CR¹—, —CR¹═CR¹—, —CO—, —SO— and/or —SO₂— moieties, where the entire ring system may be mono- or polysubstituted by the (i), (ii), (iii), (iv) and/or (v) radicals specified as substituents for the R radicals;
aryl or hetaryl, to each of which may be fused further saturated or unsaturated 5- to 7-membered rings whose carbon skeleton may be interrupted by one or more —O—, —S—, —NR¹—, —N═CR¹—, —CR¹═CR¹—, —CO—, —SO— and/or —SO₂— moieties, where the entire ring system may be mono- or polysubstituted by the (i), (ii), (iii), (iv), (v) radicals specified as substituents for the R radicals, and/or aryl- and/or hetarylazo, each of which may be mono- or polysubstituted by C₁-C₁₀-alkyl, C₁-C₆-alkoxy and/or cyano;
Y is —O—or —S—;
Z is a bridging member having at least one aromatic or heteroaromatic radical, where the Y groups are bonded to the aromatic or heteroaromatic radical;
x is from 2 to 6 when the B^{b1} and B^{b2} radicals are each a radical of the formula (a);
is 0 for all further definitions of the B^{b1} and B^{b2} radicals;
n is from 0 to 8, where x+n≦8 and n≠0 when x=0;
n1 is from 0 to 2.

6. The fluorescence conversion solar cell according to claims 1 to 5, which comprises at least one fluorescent dye from the group of the terrylenetetracarboximides and terrylenedicarboximides.

7. The fluorescence conversion solar cell according to claims 1 to 6, which comprises at least one fluorescent dye based on terrylenecarboxylic acid derivatives in combination with at least one fluorescent dye from the group of the perylenecarboxylic acid derivatives, naphthalenecarboxylic acid derivatives, isoviolanthrone derivatives and violanthrone derivatives.

8. The fluorescence conversion solar cell according to claims 1 to 7, which comprises at least one fluorescent dye based on terrylenecarboxylic acid derivatives in combination with at least one fluorescent dye from the group of the perylenetetracarboximides, perylenetetracarboxylic monoanhydride monoimides, perylenetetracarboxylic dianhydrides, perylenedicarboximides, perylenedicarboxylic anhydrides, perylenedicarboxylic esters, perylenedicarboxamides, polychromophores which have perylene units but do not comprise any terrylene units, naphthalenetetracarboximides, naphthalenedicarboximides, isoviolanthrones and violanthrones.

9. The fluorescence conversion solar cell according to claims 1 to 8, in which the polymer additionally comprises at least one stabilizing additive from the group of the light stabilizers and oxidation stabilizers.

10. The fluorescence conversion solar cell according to claims 1 to 9, which comprises a polymer from the group of the polyacrylates and polycarbonates.

11. The fluorescence conversion solar cell according to claims 1 to 10, which has a white diffuser on the lower side of the lowermost panel.

12. The fluorescence conversion solar cell according to claims 1 to 11, which has a bandpass filter on the upper side of the uppermost panel.

13. The fluorescence conversion solar cell according to claims 1 to 12, which is based on at least two panels which have been doped and/or coated with fluorescent dyes which absorb and emit at different wavelengths of the electromagnetic spectrum.
